(19) United States
(12) Patent Application Publication
(10) Pub. No.: US 2008/0012149 A1
(43) Pub. Date: Jan. 17, 2008

(54) Semiconductor chip structure

(75) Inventor: Te-Wei Chen, Chupei City (TW)

Correspondence Address: BIRCH STEWART KOLASCH & BIRCH, PO BOX 747, FALLS CHURCH, VA, 22040-0747, US

(73) Assignee: SILICONMOTION INC.

(21) Appl. No.: 11/487,304

(22) Filed: Jul. 17, 2006

(51) Int. Cl. H01L 23/48

(52) U.S. Cl. 257/780; 257/E23.02; 257/737

(57) ABSTRACT

A semiconductor chip structure includes a top metal layer and an inter-layer dielectric under the top metal layer. The top metal layer includes a bonding pad area and a non-bonding pad area. The inter-layer dielectric includes at least one first via disposed under the bonding pad area, and a plurality of conventional second vias disposed under the non-bonding pad area. The size of the first via is much larger than the size of the second via to improve bonding pad reliability. The cross section of the first via is a rectangular, a square, or a polygonal. The top metal layer has a predefined thickness to improve a yield of a wire bonding.

### BACKGROUND

1. Field of Invention

The present invention relates to a semiconductor chip structure. More particularly, the present invention relates to a bonding pad with larger via below.

2. Description of Related Art

Access to an electrical connection with an external circuit is required for an IC chip to function properly, and an IC device has to be packaged to prevent damage from external force or environmental factors during conveyance or pick-and-place procedures. Electronic packaging allows an IC device to perform a predefined function under an organized structure and provides protection for it and therefore is a necessary process in integrated circuit production.

Wire bonding technology is commonly used in IC package processes. The common IC package processes are wire bonding, tape automated bonding (TAB), and flip chip (FC). In a wire bonding process, a chip is positioned on a lead frame first, and an end of a bonding wire, which is a metal wire made of Al or Au, is press fitted on a pad of the chip. Then, the other end of the metal wire is press fitted on a pin of the lead frame.

However, the conventional arrangement of vias under the bonding pad is consisted of uniform and tiny square array. For example, a 60 μm×60 μm bonding pad may has ten thousand conventional 0.28 μm×0.28 μm vias below. Failure opening of the tiny vias may result in reducing the reliability of the electric connecting of the bonding pad. The thickness of the top metal layer may affect the quality of wire bonding process. For example, the inter-layer dielectric may be cracked caused by the heavy bonding pressure. The bonding wire and bonding pad may be easily separated and result in an IC short circuit during IC packaging caused by the slight bonding pressure.

For the forgoing reasons, there is a need for improving the reliability of the bonding wire and the quality of IC package.

### SUMMARY

It is therefore an objective of the present invention to provide a semiconductor chip structure to improve reliability of the bonding pad by the via arrangement.

It is another an objective of the present invention to provide a semiconductor chip structure to prevent the inter-layer dielectric cracking caused by heavy bonding pressure.

It is still another an objective of the present invention to provide a semiconductor chip structure to prevent separation between bonding wire and bonding pad caused by slight bonding pressure.

The present invention provides a semiconductor chip structure including a top metal layer and an inter-layer dielectric. The top metal layer includes a bonding pad area and a non-bonding pad area, wherein an electrical connection is established to connect the bonding pad area to an external circuit. The inter-layer dielectric disposed under the top metal layer includes at least a first via disposed under the bonding pad area, and each of the first via is filled with a first via plug. The inter-layer dielectric includes a plurality of second vias disposed under the non-bonding pad area, and each of the second vias is filled with a second via plug. The size of the first via is much larger than the size of the second vias to improve a reliability of the electrical connection. The size of the first via is 8 times larger than the size of the second vias, wherein an arrangement of the second vias is a 0.28 μm×0.28 μm square array. The size of the first via is proximate to the size of the bonding pad area. The size of the first via is slightly larger than the size of the bonding pad area. The material of the first via and the second vias is a metal. The material of the first via and the second vias is a tungsten (W). The cross section of the first via is a square, a rectangle, or a polygon. The material of the top metal layer is an Al—Cu alloy or an aluminum (Al). The top metal layer has a predefined thickness; the predefined thickness is proximate to 0.8 μm to improve a yield of the bonding pad area during wire bonding. The material of the inter-layer dielectric is a low-k material.

The invention also provides a bonding pad structure comprising a top metal layer and an inter-layer dielectric. The top metal layer has a bonding pad area, wherein the bonding pad area is connected to an external circuit by an electrical connection. The inter-layer dielectric disposed under the top metal layer having a first via disposed under the bonding pad area, and the size of the first via is proximate to the size of the bonding pad area to improve reliability of the electrical connection, wherein the first via is filled with a first via plug. The size of the first via is slightly larger than the size of the bonding pad area. The top metal layer further includes a non-bonding pad area, and the inter-layer dielectric further includes a plurality of second vias disposed under the non-bonding pad area, wherein each of the second vias is filled with a second via plug. The arrangement of the second vias is a 0.28 μm×0.28 μm square array. The material of the first via and the second vias is a metal. The material of the first via and the second vias is a tungsten (W). The cross section of the first via is a square, a rectangle, or a polygon. The material of the top metal layer is an Al—Cu alloy or an aluminum (Al). The top metal layer has a predefined thickness; the predefined thickness is proximate to 0.8 μm to improve a yield of the bonding pad area during wire bonding. The material of the inter-layer dielectric is a low-k material.

As embodied and broadly described herein, the invention provides a semiconductor chip structure for improving reliability of the bonding wire and quality of IC package.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 illustrates a lateral view diagram according to a preferred embodiment of this invention;

FIG. 2 illustrates a top view diagram according to the preferred embodiment of this invention;

FIG. 3 illustrates a top view diagram according to another preferred embodiment of this invention; and

FIG. 4 illustrates a top view diagram according to another preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

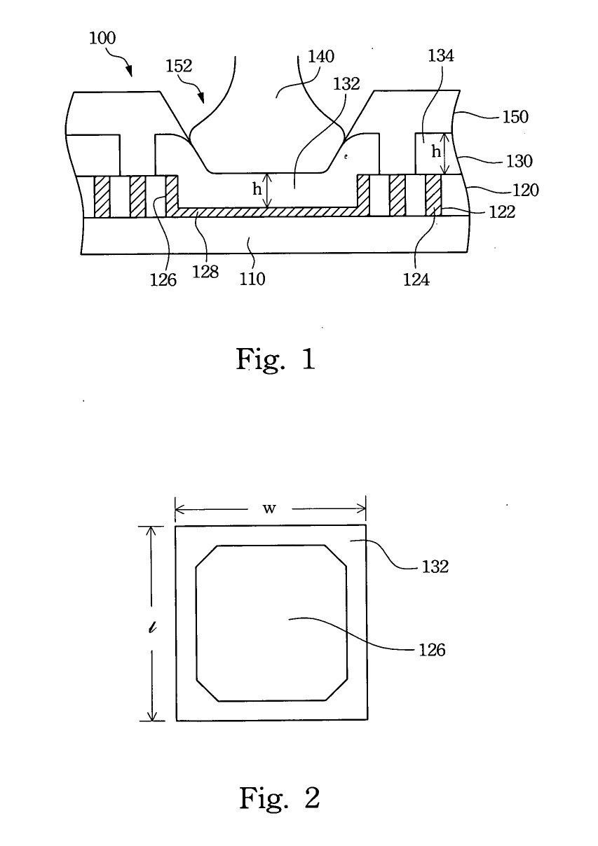

FIG. 1 illustrates a lateral view diagram according to a preferred embodiment of the semiconductor chip structure. The semiconductor chip structure 100 has a top metal −1 layer 110, an inter-layer dielectric (ILD) 120 formed on the top metal −1 layer 110, a top metal layer 130 formed on the ILD 120, and a passivation layer 150 formed on the top metal layer 130. The top metal layer 130 has a plurality of bonding pad areas 132 and a plurality of non-bonding pad areas 134. The ILD 120 has a plurality of first vias 126 disposed under the bonding pad area 132. The bonding pad area 132 may have several first vias 126 disposed below, or may have only one first via 126 disposed below as illustrated in this embodiment. The non-bonding pad area 134 may also have a plurality of second vias 122 disposed below. For example, the arrangement of the second vias 122 is a 0.28 μm×0.28 μm square array. The first via 126 is smaller than the bonding pad area 132 but at least 8 times larger than the second via 122. The passivation layer 150 has a plurality of openings 152 disposed on the bonding pad area 132 to expose the bonding pad area 132 under the passivation layer 150 to electrically connect to an external circuit. A first via plug 128 is formed within the first via 126 to connect the bonding pad area 132 to the top metal −1 layer 110, and the bonding pad area 132 and the external circuit is electrically packaged by a bonding wire 140 on the bonding pad area 132. A second via plug 124 is formed within the second via 122 to establish interconnection between the non-bonding pad area 134 and the top metal −1 layer 110. The material of the first via plug 128 and the second via plug 124 may be a metal. The material of the first via plug 128 and the second via plug 124 may be a tungsten (W). The cross section of the first via 126 is a square, a rectangle, or a polygon. The material of the top metal layer 130 is an Al—Cu alloy or an aluminum (Al). The material of the ILD 120 is a low-k material.

The size of the first via 126 is larger than the size of the second via 122. Thus the first via plug 128 cannot fill the fist via 126 as completely as the second via plug 124 does to the second via 122, but form a layer of the first via plug 128 in the first via 126. An etch back process or a chemical mechanical polish (CMP) is subsequently utilized to remove a redundant material. The top metal layer 130 has a thicker thickness h to completely fill the first via 126. The ideal thickness h is about 0.8 μm. The bonding pad area 132 of the semiconductor chip structure 100 is connected to the pin of the external circuit by the bonding wire 140.

FIG. 2 illustrates a top view diagram according to the preferred embodiment of the semiconductor chip structure. In this embodiment, only one first via 126 is disposed under the bonding pad area 132. The size of the first via 126 is slightly smaller than the bonding pad area 132 above. The size of the bonding pad area is shown in FIG. 2, the length l is about 60 μm, and the width w is about 60 μm. The cross section of the first via 126 may be a square, a rectangle, or a polygon.

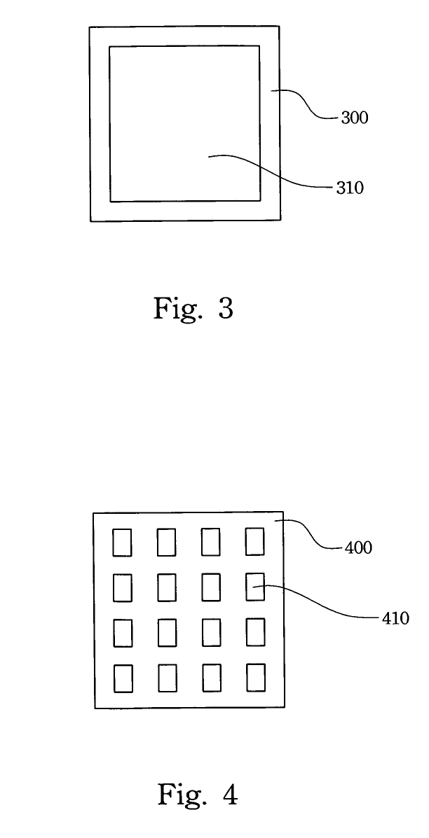

FIG. 3 illustrates a top view diagram according to another preferred embodiment of the semiconductor chip structure. In this embodiment, only one first via 310 is disposed under the bonding pad area 300. The size of the first via 310 is slightly larger than the bonding pad area 300 above. The cross section of the first via 310 may be a square, a rectangle, or a polygon.

FIG. 4 illustrates a top view diagram according to another preferred embodiment of the semiconductor chip structure. In this embodiment, the first vias 410 are disposed under the bonding pad area 400. The size of the first via 410 is still much larger than the size of the second vias 122 in FIG. 1. The cross section of the first via 410 may be a square, a rectangle, or a polygon.

The invention has following advantages. The contact area of the top metal −1 layer and the bonding pad area is increased to improve reliability the electrical connection of the bonding pad by enlarging the first via and the first via plug. The thickness of the top metal layer in the invention (0.8 μm) is proximate to 2 times of the thickness of the conventional top metal layer (0.3 μm˜0.4 μm), thus it may prevent the ILD from cracking caused by heavy bonding pressure during wire bonding process or prevent separation between the bonding wire and the bonding pad caused by slight bonding pressure. Therefore, the yield of the electric package can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor chip structure, comprising:
a top metal layer comprising a bonding pad area and a non-bonding pad area, wherein the bonding pad area is connected to an external circuit by an electrical connection; and
an inter-layer dielectric disposed under the top metal layer, comprising:
at least a first via disposed under the bonding pad area, and each of the first via is filled with a first via plug, and
a plurality of second vias disposed under the non-bonding pad area, and each of the second vias is filled with a second via plug, wherein a size of the first via is much larger than a size of the second vias to improve a reliability of the electrical connection.

2. The semiconductor chip structure of claim 1, wherein the size of the first via is at least 8 times larger than the size of the second vias, wherein an arrangement of the second vias is a 0.28 μm×0.28 μm square array.

3. The semiconductor chip structure of claim 1, wherein the size of the first via is proximate to a size of the bonding pad area.

4. The semiconductor chip structure of claim 1, wherein the size of the first via is slightly larger than the size of the bonding pad area.

5. The semiconductor chip structure of claim 1, wherein a material of the first via and the second vias is a metal.

6. The semiconductor chip structure of claim 5, wherein the material of the first via and the second vias is a tungsten (W).

7. The semiconductor chip structure of claim 1, wherein a cross section of the first via is a square, a rectangle, or a polygon.

8. The semiconductor chip structure of claim 1, wherein a material of the top metal layer is an Al—Cu alloy or an aluminum (Al).

9. The semiconductor chip structure of claim 1, wherein the top metal layer has a predefined thickness, wherein the predefined thickness is proximate to 0.8 μm to improve a yield of the bonding pad area during wire bonding.

10. The semiconductor chip structure of claim 1, wherein a material of the inter-layer dielectric is a low-k material.

11. A bonding pad structure, comprising:
a top metal layer having a bonding pad area, wherein the bonding pad area is connected to an external circuit by an electrical connection; and
an inter-layer dielectric disposed under the top metal layer having a first via disposed under the bonding pad area, and a size of the first via is proximate to a size of the bonding pad area to improve a reliability of the electrical connection, wherein the first via is filled with a first via plug.

12. A bonding pad structure of claim 1, wherein the size of the first via is slightly larger than the size of the bonding pad area.

13. A bonding pad structure of claim 1, wherein the top metal layer further comprises a non-bonding pad area, the inter-layer dielectric further comprises a plurality of second vias disposed under the non-bonding pad area, wherein each of the second vias is filled with a second via plug, wherein an arrangement of the second vias is a 0.28 μm×0.28 μm square array.

14. A bonding pad structure of claim 13, wherein a material of the first via and the second vias is a metal.

15. A bonding pad structure of claim 14, wherein the material of the first via and the second vias is a tungsten (W).

16. A bonding pad structure of claim 11, wherein a cross section of the first via is a square, a rectangle, or a polygon.

17. A bonding pad structure of claim 11, wherein a material of the top metal layer is an Al—Cu alloy or an aluminum (Al).

18. A bonding pad structure of claim 11, wherein the top metal layer has a predefined thickness, wherein the predefined thickness is proximate to 0.8 μm to improve a yield of the bonding pad area during wire bonding.

19. A bonding pad structure of claim 11, wherein a material of the inter-layer dielectric is a low-k material.
